(19) United States
(12) Patent Application Publication
(10) Pub. No.: US 2026/0343899 A1
(43) Pub. Date: Oct. 29, 2026

(54) SELF-RECTIFYING RESISTIVE MEMORY DEVICE AND METHOD OF MANUFACTURING THE SAME

(71) Applicant: PUSAN NATIONAL UNIVERSITY INDUSTRY-UNIVERSITY COOPERATION FOUNDATION, Busan (KR)

(72) Inventors: Beomjin JEONG, Busan (KR); Jeong Hyeon Son, Busan (KR)

(21) Appl. No.: 19/653,368

(22) Filed: Apr. 21, 2026

(30) Foreign Application Priority Data
Apr. 25, 2025 (KR) 10-2025-0054806

(51) Int. Cl. H10B 63/00

(52) U.S. Cl. CPC H10B 63/24

(57) ABSTRACT

A self-rectifying resistive memory device including an active layer comprising 2-D perovskite and a ferroelectric is disclosed. The device is capable of low-voltage driving due to the low activation energy of the 2-D perovskite. Furthermore, the device exhibits excellent self-rectifying characteristics without a separate diode, as polarization of the ferroelectric is induced by intermolecular interaction between the ferroelectric and the 2-D perovskite.

### CROSS-REFERENCE TO RELATED APPLICATIONS

The present application claims priority to and the benefit of Korean Patent Application No. 10-2025-0054806, filed on Apr. 25, 2025, in the Korean Intellectual Property Office, the entire disclosure of which is incorporated herein by reference.

### FIELD

The present disclosure relates to a self-rectifying resistive memory device and a method of manufacturing the same.

### BACKGROUND

Recently, as application fields such as artificial intelligence, the Internet of Things, and high-performance computing are spread, there is a growing interest in a next-generation nonvolatile memory (NVM) technology capable of rapidly storing and stably processing a large amount of data. Among the application fields, a resistive memory device having potential power capable of reducing the Von Neumann bottleneck phenomenon by a simple cell structure, high power efficiency, and a nonvolatile characteristic, that is, a memristor, has been in the spotlight as a promising next-generation memory technology.

In general, the resistive memory device has a cross-bar array structure that is an interleaved array structure, can store data in a high resistance state (HRS) and a low resistance state (LRS), can store data in each cell, and can read or delete data stored in each cell. However, in the cross-bar array structure, a malfunction may occur, such as that a switching operation is arbitrarily performed by a leakage current generated from an adjacent memory cell because several cells are connected to one electrode. In general, in order to solve such a problem, a scheme using a 1 selector-1 resistor (1S1R) structure in which selectors are integrated along with resistive memory cells in a one-to-one way has been proposed. The scheme has a disadvantage in that a problem, such as an increase of process complexity, an increase of a cell area, or a rise of a driving voltage, may also occur due to the addition of the selectors.

As a scheme for improving such a driving voltage problem, recently, a two-dimensional (2-D) perovskite semiconductor material capable of low voltage driving has been in the spotlight. In particular, the 2-D perovskite is characterized in that it can change a resistance state even by a low voltage because the 2-D perovskite has low activation energy. However, the 2-D perovskite material has a disadvantage in that it is vulnerable to heat and moisture and thus has problems in that it is degraded and has reduced performance when the 2-D perovskite material is applied to a high temperature process or a cross-bar array structure and a multi-layer thin film structure in which top/bottom electrodes are intersected.

Accordingly, there is a need to develop a new resistive memory device capable of using low voltage driving, that is, an advantage of the 2-D perovskite and also preventing the degradation of perovskite occurring in the multi-layer thin film structure and capable of self-rectifying.

### SUMMARY

Various embodiments relate to a resistive memory device capable of self-rectifying and a method of manufacturing the same and are directed to providing a resistive memory device capable of changing its resistance state even at a low voltage by two-dimensional (2-D) perovskite included in an active layer and also having an improved self-rectifying characteristic by ferroelectric.

In an embodiment, a self-rectifying resistive memory device includes a bottom electrode, a top electrode, and an active layer interposed between the bottom electrode and the top electrode. The active layer includes a channel configured to penetrate the inside of the active layer and to connect the top electrode and the bottom electrode and ferroelectric. The channel includes two-dimensional (2-D) perovskite. An average diameter of the channels is 0.1 μm or greater and 2 μm or less.

The 2-D perovskite may be present in an amount of 10 to 90 parts by weight based on 100 parts by weight of the ferroelectric.

The ferroelectric may have a polarization value of 1 μC/cm² or more and 10 μC/cm² or less.

The ferroelectric may have a polarization value of 5 μC/cm² or more and 7 μC/cm² or less.

The 2-D perovskite may be a compound expressed by Chemical Formula 1:

Y₂MX₄ [Chemical Formula 1]

In the Chemical Formula 1,
the Y is butyl ammonium (BA), pentylammonium (PA), hexylammonium (HA), ammonium valeric acid (AVA), naphthylmethyl ammonium (NMA), phenylmethylammonium (PMA), or phenylethyl ammonium (PEA),
the M is Cu, Fe, Sn, Zn, Pb, Mn, Ge, Ni, Co, Cr, Pd, Cd, or Yb, and
the X is F, Cl, Br, or I.

The 2-D perovskite may include one or more selected from a group consisting of BA₂PbI₄, PEA₂PbI₄, and BA₂PbCl₄.

The ferroelectric may include a (co)polymer including one or more monomers selected from a group consisting of vinylidene fluoride, trifluoroethylene, chlorofluoroethylene, and chlorotrifluoroethylene.

The ferroelectric may include one or more selected from a group consisting of PVDF, P(VdF-TrFE), P(VdF-TrFE-CFE), and P(VdF-TrFE-CTFE).

The thickness of the active layer may be 0.1 μm or greater and 1 μm or less.

The top electrode may include one or more selected from a group consisting of Ag, Au, Al, Cu, Ni, Mg, Fe, Cr, Ti, Pt, Ru, Co, Mo, W, Li, Na, K, Cs, and Zn.

The bottom electrode may include one or more selected from a group consisting of ITO, FTO, AZO, IZO, ZTO, and IZTO.

In an embodiment, a method of manufacturing a self-rectifying resistive memory device includes preparing an active layer slurry including two-dimensional (2-D) perovskite, ferroelectric, and a solvent, forming an active layer by coating the active layer slurry on one surface of a bottom electrode, and stacking a top electrode on a surface of the active layer opposite to the bottom electrode. The 2-D perovskite may be used in an amount of 10 to 90 parts by weight, based on 100 parts by weight of the ferroelectric included in the active layer slurry.

The forming of the active layer may include coating the active layer slurry by a spin-coating method.

The self-rectifying resistive memory device according to an embodiment of the present disclosure has advantages in that the self-rectifying characteristic and the low voltage driving characteristic are excellent because the channel including the 2-D perovskite and the ferroelectric are included in the active layer and that a flow of current is made smooth by controlling the size of the diameter of the channel including the 2-D perovskite.

### BRIEF DESCRIPTION OF THE DRAWINGS

FIG. 1 is a side view schematically illustrating a shape of a part of a self-rectifying resistive memory device according to an embodiment of the present disclosure.

FIG. 2 is a diagram illustrating an operation mechanism of the self-rectifying resistive memory device according to an embodiment of the present disclosure. Specifically, from FIG. 2, it may be seen that as a positive voltage is applied to the self-rectifying resistive memory device in a high resistance state (HRS), a SET operation in which the self-rectifying resistive memory device switches to a low resistance state (LRS) is performed and a conductive filament (Ag⁺-doped CF) is formed in the LRS. Furthermore, from FIG. 2, it may be seen that when a negative voltage is applied to the self-rectifying resistive memory device, the conductive filament is ruptured (Rupture of CF), resulting in a RESET operation in which the self-rectifying resistive memory device switches to the high resistance state (HRS).

FIG. 3 is a diagram schematically illustrating a form of the self-rectifying resistive memory device according to an embodiment of the present disclosure. Specifically, the top left of FIG. 3 is a perspective view of the resistive memory device, illustrating a form in which an active layer is stacked on one surface of an ITO bottom electrode and a plurality of Ag top electrodes is stacked and spaced apart from each other on a surface of the active layer opposite to the bottom electrode. The bottom left of FIG. 3 is a side view of a part of the self-rectifying resistive memory device at the top left, which is the same as FIG. 1. The right side of FIG. 3 is a diagram illustrating a state in which the polarity b-axes of the ferroelectric are aligned in a horizontal direction by an intermolecular interaction between the 2-D perovskite and the ferroelectric at an interface between a 2-D perovskite-containing channel and the ferroelectric.

FIG. 4 is a diagram simply illustrating a process of manufacturing the self-rectifying resistive memory device according to an embodiment of the present disclosure. In the manufacturing process, first, an active layer (P(VDF-TrFE)+BA₂PbI₄) is formed on a bottom electrode (Cleaned ITO glass) by spin-coating active layer slurry. Next, the self-rectifying resistive memory device is manufactured by stacking a plurality of top electrodes (Ag electrodes) on the other surface of the active layer by using a thermal evaporation process.

FIG. 5A is an atomic force microscope (AFM) image of the active layer of resistive memory device according to the Comparative Example 1.

FIG. 5B is an AFM image of the active layer of self-rectifying resistive memory device according to the Embodiment 1.

FIG. 5C is an AFM image of the active layer of self-rectifying resistive memory device according to the Embodiment 2.

FIG. 5D is an AFM image of the active layer of self-rectifying resistive memory device according to the Embodiment 3.

FIG. 5E is an AFM image of the active layer of self-rectifying resistive memory device according to the Embodiment 4.

FIG. 6A is a field emission type scanning electron microscope (FE-SEM) image of the active layer of the resistive memory device according to Comparative Example 1.

FIG. 6B is an FE-SEM image of the active layer of the self-rectifying resistive memory device according to Embodiment 1.

FIG. 6C is an FE-SEM image of the active layer of the self-rectifying resistive memory device according to Embodiment 2.

FIG. 6D is an FE-SEM image of the active layer of the self-rectifying resistive memory device according to Embodiment 3.

FIG. 6E is an FE-SEM image of the active layer of the self-rectifying resistive memory device according to Embodiment 4.

FIG. 7 is a resistance switching I-V curve illustrating the results of DC voltage sweep experiments performed on the self-rectifying resistive memory device of the Embodiment 3.

FIG. 8 is a resistance switching I-V curve illustrating the results of DC voltage sweep experiments performed on the resistive memory device of the Comparative Example 1.

FIG. 9 is a resistance switching I-V curve illustrating the results of DC voltage sweep experiments performed on the resistive memory device of the Comparative Example 2.

FIG. 10 is a graph illustrating currents measured at +0.1 V and −0.1 V by applying arbitrary voltages in the LRS of the self-rectifying resistive memory device of the Embodiment 3. In the graph, an x axis denotes applied voltages, a y axis on the left denotes currents measured at +0.1 V, and a y axis on the right denotes currents measured at −0.1 V.

FIG. 11A is a resistance switching I-V curve illustrating the results of DC voltage sweep experiments performed by date on the self-rectifying resistive memory device according to Embodiment 3 after being left under room temperature and atmospheric conditions for 32 days to evaluate its stability over time.

FIG. 11B is a resistance switching I-V curve illustrating the results of DC voltage sweep experiments performed on the self-rectifying resistive memory device according to Embodiment 3 in a temperature range of 25 to 85 °C to evaluate its thermal stability.

FIG. 12A is a graph in which current values of the self-rectifying resistive memory device of the Embodiment 3 in ON and OFF states according to times at a read voltage of +0.1 V were measured and recorded for 10⁴ seconds.

FIG. 12B is a graph in which current values of the self-rectifying resistive memory device of the Embodiment 3 in the ON and OFF states according to the number of cycles by performing a total of 200 switching cycles were measured and recorded.

### DETAILED DESCRIPTION

Hereinafter, each component of the present disclosure is described more specifically so that a person having ordinary knowledge in the art to which the present disclosure pertains can easily practice the present disclosure, but this is merely an example and the scope of right of the present disclosure is not restricted by the following contents.

A term “include” used in this specification is used to list materials, compositions, devices, and methods which are useful in the present disclosure, and is not limited to the listed example.

A term “about” or “substantially” that is used in this specification is used as the category of a numerical value or degree thereof or a meaning close to the numerical value or degree by taking a unique manufacturing and material tolerance and is used to prevent an infringer from illegally using disclosed contents in which accurate or absolute numerical values provided in order to help understanding of the present disclosure are mentioned.

In this specification, when it is said that one component is provided “on” the other component, it means that another component may be further disposed without excluding that another component is disposed between the two components, unless explicitly described to the contrary.

In this specification, “two-dimensional (2-D) perovskite” refers to a compound in which metal halide octahedron structure units ([MX₆]⁴⁻) (wherein M is a divalent metallic cation and X is a halogen anion) are arranged on a plane to form an inorganic layer and a monovalent organic cation is inserted between the inorganic layers to form a stratified structure. For example, the 2-D perovskite may be BA₂PbI₄, that is, a compound in which butylammonium (BA) acts as an organic layer as an organic cation and [PbI₆]⁴— octahedron forms a 2-D plane structure.

In this specification, an “average diameter of a channel” refers to a value obtained by measuring the lengths of about 10 channels monitored by photographing a surface of an active layer through a field emission type scanning electron microscope (FE-SEM) and arithmetically averaging the measured diameters.

Hereinafter, embodiments of the present disclosure are described more specifically.

Embodiments of the present disclosure provide a self-rectifying resistive memory device.

According to an embodiment of the present disclosure, the self-rectifying resistive memory device includes a bottom electrode, a top electrode, and an active layer interposed between the bottom electrode and the top electrode. The active layer includes a channel that penetrates the active layer and connects the top electrode and the bottom electrode and ferroelectric. The channel includes 2-D perovskite. An average diameter of the channel is 0.1 μm or greater and 2 μm or less. Specifically, the active layer including the channel including the 2-D perovskite and the ferroelectric may be the active layer of a single layer. The 2-D perovskite is vulnerable to heat and moisture. If the 2-D perovskite is manufactured as the active layer of a single layer that minimizes a process for a thin film, evaporation, or etching, it is possible to minimize damage to the 2-D perovskite material. Furthermore, the active layer of the single layer can have a smaller cell size as a simple structure. Accordingly, an increase in the degree of integration and memory capacity may be expected.

The 2-D perovskite has an advantage in that an energy barrier necessary for a movement of ions, that is, activation energy, is low. Accordingly, the self-rectifying resistive memory device in which the channel including the 2-D perovskite is included in the active layer according to an embodiment of the present disclosure has an advantage in that resistance switching is possible even at a low voltage. Specifically, the channel penetrates the active layer and also comes into contact with the top electrode and the bottom electrode, thereby enabling a movement of ions and electrons. A low voltage driving characteristic of the self-rectifying resistive memory device can be improved because the channel includes the 2-D perovskite having low activation energy. Furthermore, the self-rectifying resistive memory device has advantages in that it is low in total power consumption and advantageous for high integration memory applications.

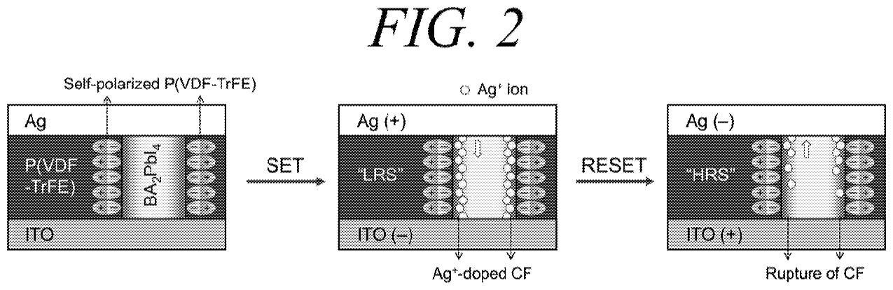

By a strong molecular interaction between the ferroelectric and the 2-D perovskite, self-alignment may be performed in the ferroelectric adjacent to the channel. Spontaneous polarization of the ferroelectric may be formed at an interface between the channel including the 2-D perovskite and the ferroelectric by the self-alignment. Accordingly, as the results of asymmetric forming of an electric field within the active layer by high polarization of the ferroelectric, in the channel including the 2-D perovskite, a movement direction of ions or electrons may be controlled in a specific direction. That is, the self-rectifying resistive memory device including the active layer, including the ferroelectric and the channel including the 2-D perovskite, may have an excellent self-rectifying characteristic like a diode. As may be seen from FIG. 2, in the self-rectifying resistive memory device according to an embodiment of the present disclosure, when a positive voltage is applied in an initial high resistance state (HRS) (i.e., a SET operation), metallic ions (Ag⁺) in the top electrode may be injected into the active layer and moved to the bottom electrode. At this time, in the low resistance state (LRS), the metallic ions may assign a doping effect by substituting lead vacancies of the 2-D perovskite. As a result, a conductive filament through which holes may move is formed so that a current can flow. Furthermore, when a negative voltage is applied (i.e., a RESET operation), the metallic ions are decomposed by a reverse electric field and return to the top electrode. As the conduction path disappears, the LRS switches to the HRS in which a current does not flow. That is, the self-rectifying resistive memory device is capable of a resistance switch operation and self-rectifying through such a method.

Specifically, the active layer may include a plurality of channels each including the 2-D perovskite. More specifically, the plurality of channels may be dispersed within the active layer in a dot pattern form or a kind of island form. Accordingly, ions and electrons can smoothly move between the top electrode and the bottom electrode through the channels containing the 2-D perovskite within the active layer.

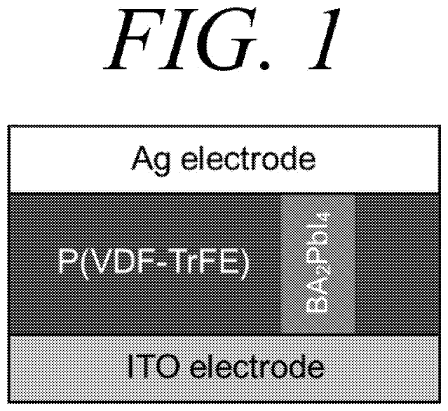

Furthermore, an average diameter of the channels may be 0.1 μm or greater and 2 μm or less. Specifically, an average diameter of the channels may mean the horizontal length of the BA₂PbI₄ channel illustrated in FIG. 1. Specifically, the diameter of the channel may be 0.1 μm or more, 0.3 μm or more, 0.5 μm or more, 0.7 μm or more, 0.9 μm or more, or 1 μm or more, and may be 2 μm or less, 1.5 μm or less, or 1 μm or less. When the diameter of the channel satisfies the range, ions and electrons can smoothly move through the channel having a sufficiently wide size. Accordingly, low voltage driving performance of the self-rectifying resistive memory device may be excellent. When the diameter of the channel is less than the range, a current may not smoothly flow through the channel. Furthermore, when the diameter of the channel exceeds the range, the rectification action by the ferroelectric may not smoothly occur because the relative content and volume of the ferroelectric decrease.

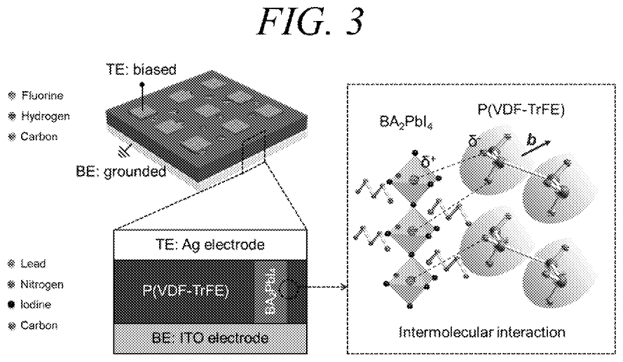

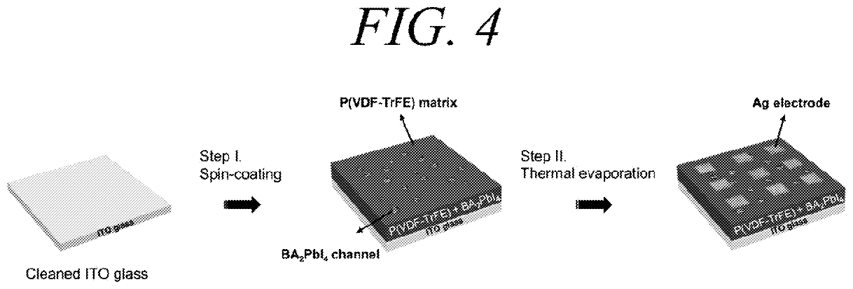

Furthermore, specifically, the self-rectifying resistive memory device may have a structure in which the active layer of a single layer is provided on one surface of a bottom electrode and a plurality of top electrodes is distributed by being spaced apart from each other. For example, as illustrated in FIG. 3A, the self-rectifying resistive memory device may have a form in which the active layer is provided on an ITO-coated glass substrate and a plurality of Ag top electrodes is distributed on the other surface of the active layer by being spaced apart from each other.

In other words, by the channel including the 2-D perovskite and the ferroelectric, the active layer can change its resistance state at a low voltage while preventing the leakage current even without a selector. By the polarization of the ferroelectric, an electric field within the active layer is asymmetrically formed, thereby providing an excellent self-rectifying characteristic. Furthermore, a current can effectively move through the active layer by the channel having a diameter of 0.1 to 2 μm.

According to an embodiment of the present disclosure, content of the 2-D perovskite may be used in an amount of 10 parts by weight or more and 90 parts by weight or less based on total 100 parts by weight of the ferroelectric. Specifically, based on the total 100 parts by weight of the ferroelectric, the content of the 2-D perovskite may be used in an amount of 10 parts by weight or more, 20 parts by weight or more, or 30 parts by weight or more and may be 90 parts by weight or less, 80 parts by weight or less, 70 parts by weight or less, 60 parts by weight or less, 50 parts by weight or less, or 40 parts by weight or less. When the content ratio of the 2-D perovskite and the ferroelectric within the active layer satisfies the range, a current can smoothly flow because the channel including the 2-D perovskite is sufficiently formed within the active layer. Furthermore, the self-rectifying characteristic of the self-rectifying resistive memory device may be excellent by the polarization of the ferroelectric because the ferroelectric is also sufficiently present.

According to an embodiment of the present disclosure, the ferroelectric may have a polarization value of 1 μC/cm² or more and 10 μC/cm² or less. Specifically, the ferroelectric may have a polarization value of 1 μC/cm² or more, 2 μC/cm² or more, 3 μC/cm² or more, 4 μC/cm² or more, or 5 μC/cm² or more, and may have a polarization value of 10 μC/cm² or less, 9 μC/cm² or less, 8 μC/cm² or less, or 7 μC/cm² or less. Preferably, the polarization value of the ferroelectric may be 5 μC/cm² or more and 7 μC/cm² or less. The polarization value of the ferroelectric is measured by a method of analyzing a polarization-voltage characteristic of a ferroelectric thin-film capacitor manufactured by the same process in a composition not including perovskite. When the polarization value of the ferroelectric satisfies the range, more effectively, an asymmetric charge distribution may be induced in the active layer. As a result, the self-rectifying characteristic of the self-rectifying resistive memory device may be excellent. Furthermore, when the polarization value satisfies the range, effects such as a rise of the self-rectifying ratio, the retention of the resistance state, and the improvement of the switching cycle characteristic can be achieved.

According to an embodiment of the present disclosure, the 2-D perovskite may be a compound expressed by Chemical Formula 1.

Y₂MX₄ [Chemical Formula 1]

In Chemical Formula 1, the Y is butyl ammonium (BA), pentylammonium (PA), hexylammonium (HA), ammonium valeric acid (AVA), naphthylmethyl ammonium (NMA), phenylmethylammonium (PMA), or phenylethyl ammonium (PEA). The M is Cu, Fe, Sn, Zn, Pb, Mn, Ge, Ni, Co, Cr, Pd, Cd, or Yb. The X is F, Cl, Br, or I. When the compound of Chemical Formula 1 is used as the 2-D perovskite, the self-rectifying resistive memory device may be driven at a low voltage through low activation energy of the 2-D perovskite and the self-rectifying characteristic may be further improved by an intermolecular interaction with the ferroelectric.

According to an embodiment of the present disclosure, the 2-D perovskite may include one or more selected from a group consisting of BA₂PbI₄, PEA₂PbI₄, and BA₂PbCl₄. Specifically, the 2-D perovskite may be BA₂PbI₄. When the listed compound, specifically, BA₂PbI₄ is used as the 2-D perovskite, the generation of the leakage current can be minimized by high insulation of BA₂PbI₄. Accordingly, the ON/OFF switching of the self-rectifying resistive memory device may be stable because the forming of the conduction filament by the injection of ions can be precisely controlled. Furthermore, the self-rectifying resistive memory device can be driven at a low voltage by low activation energy of BA₂PbI₄.

According to an embodiment of the present disclosure, the ferroelectric may include a (co)polymer including one or more monomers selected from a group consisting of vinylidene fluoride, trifluoroethylene, chlorofluoroethylene, and chlorotrifluoroethylene. When the ferroelectric is a polymer or a copolymer including at least one monomer, internal polarization of the ferroelectric can be more effectively induced by a high dielectric constant. Accordingly, the self-rectifying characteristic of the self-rectifying resistive memory device may be excellent. Furthermore, in the case of the copolymer, a degree of freedom of a polymer chain can be controlled because content of heterogeneous monomers within the copolymer is adjusted. Accordingly, the self-rectifying resistive memory device may be suitable for being applied to a flexible device or a body-implantable device.

According to an embodiment of the present disclosure, the ferroelectric may include one or more selected from a group consisting of PVdF, P(VdF-TrFE), P(VdF-TrFE-CFE), and P(VdF-TrFE-CTFE). Specifically, the ferroelectric may be a copolymer (P(VdF-TrFE)) of vinylidene fluoride and trifluoroethylene. The polymer or copolymer may have an excellent self-rectifying characteristic because the polarization state of the polymer or copolymer can be changed even at a low voltage by a low compulsory field. Furthermore, when the active layer includes the polymer or copolymer as the ferroelectric, the active layer can be stably switched even at a low voltage. Furthermore, the P(VdF-TrFE) is capable of a solution process and also has high mechanical flexibility, thereby facilitating the manufacturing of a flexible device.

According to an embodiment of the present disclosure, the thickness of the active layer may be 0.1 μm or more and 1 μm or less. Specifically, the thickness of the active layer may be 0.1 μm or more, 0.2 μm or more, or 0.3 μm or more and may be 1 μm or less, 0.75 μm or less, or 0.5 μm or less. When the thickness of the active layer satisfies the aforementioned range, ions and electrons may smoothly move through the active layer, while simultaneously preventing sneak current that may occur if the thin film of the active layer is excessively thin. Furthermore, in the range of the thickness, both the self-rectifying characteristic and the low voltage driving characteristic may be excellent.

According to an embodiment of the present disclosure, a top electrode may include one or more selected from the group consisting of Ag, Au, Al, Cu, Ni, Mg, Fe, Cr, Ti, Pt, Ru, Co, Mo, W, Li, Na, K, Cs, and Zn. Specifically, the top electrode may include Ag. The top electrode is a highly conductive metal substrate including a metallic element, may have excellent compatibility with an organic materials because the top electrode may be subjected to thermal evaporation at a low temperature, and can transfer metallic cations to the bottom electrode through the active layer because the top electrode is placed on the active layer.

According to an embodiment of the present disclosure, the bottom electrode may include one or more selected from a group consisting of indium tin oxide (ITO), fluorine tin oxide (FTO), aluminum zinc oxide (AZO), indium zinc oxide (IZO), zinc tin oxide (ZTO), and indium zinc tin oxide (IZTO). Specifically, the bottom electrode may be an electrode in which oxide such as ITO is coated on a glass substrate. The bottom electrode is a high conductive substrate including the oxide, and can stably maintain a flow of current. The oxide may be formed on the glass substrate as a thin film, thereby being advantageous for reducing an overall size of the self-rectifying resistive memory device.

Embodiments of the present disclosure provide a method of manufacturing the self-rectifying resistive memory device.

Hereinafter, a method of manufacturing the self-rectifying resistive memory device according to an embodiment of the present disclosure will be described. Descriptions overlapping with the above description of the device may be omitted.

According to an embodiment of the present disclosure, the method of manufacturing the self-rectifying resistive memory device may include preparing an active layer slurry including the 2-D perovskite, the ferroelectric, and a solvent, forming the active layer by coating the active layer slurry on one surface of the bottom electrode, and stacking the top electrode on the other surface of the active layer that does not come into contact with the bottom electrode. The content of the 2-D perovskite may be used in an amount of 10 parts by weight or more and 90 parts by weight or less based on the total 100 parts by weight of the ferroelectric included in the active layer slurry. According to the method of manufacturing the self-rectifying resistive memory device, the self-rectifying resistive memory device having an excellent self-rectifying characteristic and a low voltage driving characteristic can be manufactured because the active layer is formed on the bottom electrode by using the 2-D perovskite and the ferroelectric.

The preparing of the active layer slurry may include adding the 2-D perovskite and the ferroelectric to the solvent. Specifically, the solvent may be an organic solvent such as dimethylformamide. The 2-D perovskite and the ferroelectric may be uniformly distributed within the active layer slurry by adding them to the organic solvent at a temperature of 60 to 80 °C and agitating the same.

In this case, the content of the 2-D perovskite may be used in an amount of 10 parts by weight or more and 90 parts by weight or less based on the total 100 parts by weight of the ferroelectric within the active layer slurry. Specifically, based on the total 100 parts by weight of the ferroelectric within the active layer slurry, the content of the 2-D perovskite may be 10 parts by weight or more, 20 parts by weight or more, or 30 parts by weight or more and may be 90 parts by weight or less, 70 parts by weight or less, or 50 parts by weight or less. When the content ratio of the 2-D perovskite and the ferroelectric within the active layer slurry satisfies the range, the channel including the 2-D perovskite within the active layer may be sufficiently formed. Accordingly, the diameter of the channel including the 2-D perovskite may satisfy the range of 0.1 μm or greater and 2 μm or less.

The forming of the active layer may include applying the active layer slurry on one surface of the bottom electrode and then drying the active layer slurry. Specifically, the active layer having a thickness of 0.1 μm or more and 1 μm or less may be formed by applying the active layer slurry and then drying the active layer slurry at a temperature of 50 °C or more and 100 °C or less so that the remaining solvent is removed.

The stacking of the top electrode may include forming the top electrode on the surface of the active layer opposite to the bottom electrode. Specifically, during the stacking of the top electrode, damage which may occur at an interface between the active layer and the top electrode can be minimized by bonding the top electrode and the active layer by using a thermal evaporation process.

According to an embodiment of the present disclosure, the forming of the active layer may include coating the active layer slurry by a spin-coating method. The forming of the active layer may include spin-coating the active layer slurry for 30 seconds or more and 2 minutes or less at a speed of 1,000 rpm or more and 1,500 rpm or less. If the spin-coating is used as a method of coating the active layer slurry, the B phase of the ferroelectric may be easily formed. Accordingly, the self-rectifying characteristic may be excellent because strong polarization of the active layer can be induced. Furthermore, the spin-coating has advantages in that reproducibility is excellent because a process is simple and rapid and the active layer of a thin film can be formed.

Hereinafter, embodiments are described in detail in order to describe the present disclosure in detail. However, the embodiments of the present disclosure may be modified in various other forms, and the scope of the present disclosure is not construed as being limited to embodiments described hereinafter. The embodiments of this specification are provided to a person having ordinary knowledge in the art to more fully describe the present disclosure.

### Embodiments and Comparative Examples

### Manufacturing Resistive Memory Device

### Embodiment 1

Active layer slurry was prepared by preparing P(VdF-TrFE) (the mole ratio 7:3 of vinylidenefluoride monomers and trifluoroethylene monomers) and BA₂PbI₄ as the ferroelectric and the 2-D perovskite, respectively, adding P(VdF-TrFE) and BA₂PbI₄ to dimethylformamide at the weight ratio of 1:0.23, and then strongly agitating them at a temperature of 70 °C. After the glass substrate coated with ITO was prepared as the bottom electrode and sequentially washed by using acetone and 2-propanol, UV—O₃ treatment was performed every 15 minutes for each washing step. Next, after the active layer slurry was applied on one surface of the bottom electrode by spin-coating at the speed of 1,500 rpm for 60 seconds, the remaining solvent was removed by drying the active layer slurry at a temperature of 70 °C for 60 minutes. The thickness of the formed active layer was about 350 nm. A plurality of channels each including the 2-D perovskite was uniformly distributed on a surface of the active layer. The diameter of each channel was about 415 nm. Next, the Ag substrate having a thickness of 100 nm was prepared as the top electrode and stacked on the other surface of the active layer through thermal evaporation u sing a shadow mask, thereby manufacturing the self-rectifying resistive memory device. In this case, the area of the self-rectifying resistive memory device was about 380 μm².

The P(VdF-TrFE) had a polarization value of 6 μC/cm² as the results of the measurement of the P(VdF-TrFE) by using a method of analyzing the polarization-voltage characteristic of the ferroelectric thin-film capacitor manufactured by the same process as the process of manufacturing the active layer in a composition not including the 2-D perovskite.

### Embodiment 2

The self-rectifying resistive memory device was manufactured by using the same method as that of the embodiment 1 except that the active layer slurry was prepared by using the P(VdF-TrFE) and BA₂PbI₄ at the weight ratio of 1:0.3 in the embodiment 1.

### Embodiment 3

The self-rectifying resistive memory device was manufactured by using the same method as that of the embodiment 1 except that the active layer slurry was prepared by using the P(VdF-TrFE) and BA₂PbI₄ at the weight ratio of 1:0.37 in the embodiment 1.

### Embodiment 4

The self-rectifying resistive memory device was manufactured by using the same method as that of the embodiment 1 except that the active layer slurry was prepared by using the P(VdF-TrFE) and BA₂PbI₄ at the weight ratio of 1:0.43 in the embodiment 1.

### Comparative Example 1

A resistive memory device was manufactured by using the same method as that of the embodiment 1 except that the active layer slurry was prepared without using the BA₂PbI₄ in the embodiment 1.

### Comparative Example 2

A resistive memory device was manufactured by using the same method as that of the embodiment 1 except that the active layer slurry was prepared without using the P(VdF-TrFE) in the embodiment 1.

### Experiment Example

### Experiment Example 1. Analyze a Shape of a Surface of the Active Layer According to the Content of the 2-D Perovskite

Shapes of surfaces of the active layers according to the embodiment and the comparative example were analyzed by using an atomic force microscope (AFM) and a field emission type scanning electron microscope (FE-SEM).

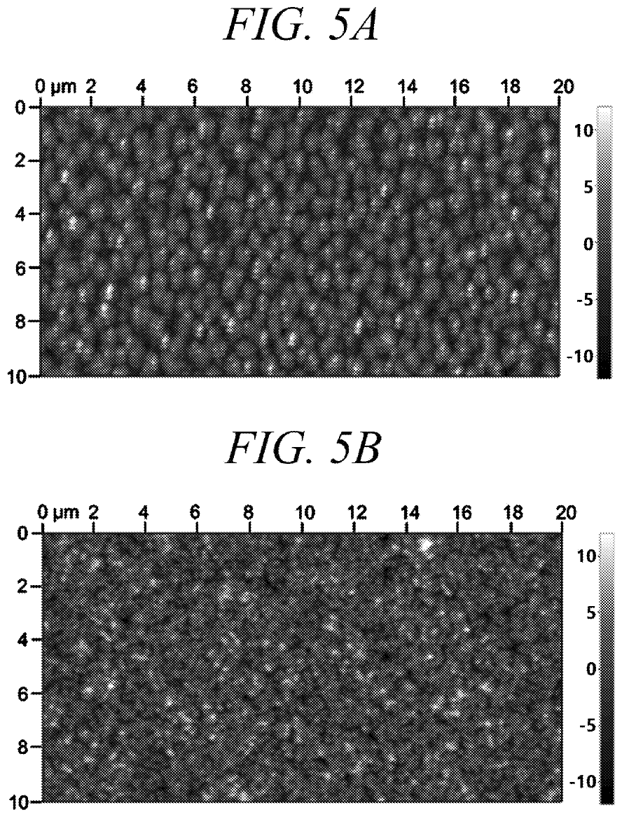

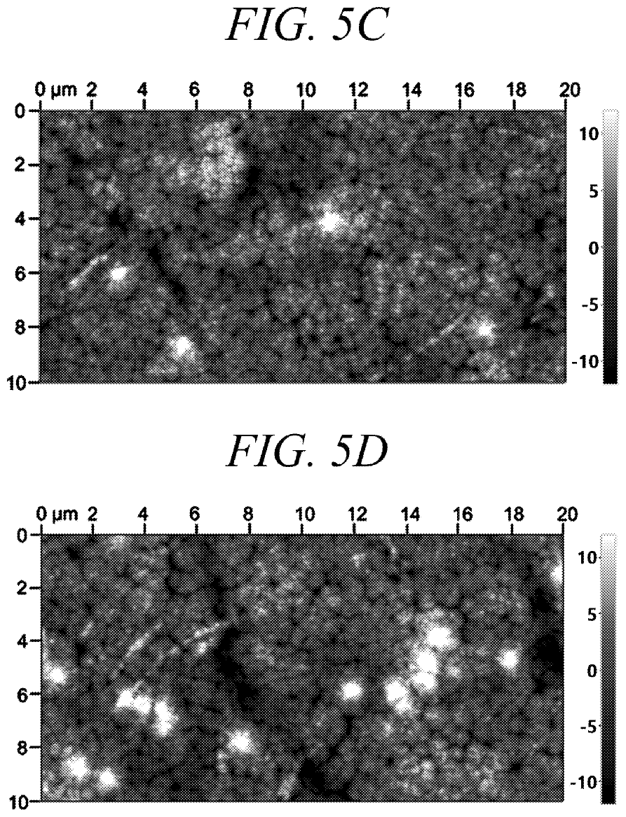

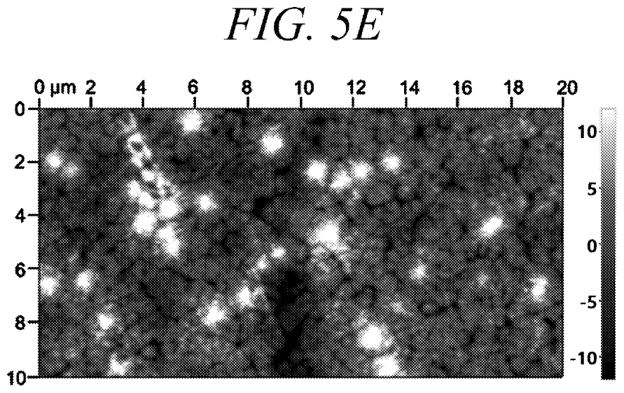

First, the active layers of the embodiment and the comparative example were measured by a contactless mode AFM (NX10, Park Systems Co.) and a distribution of the channels including the 2-D perovskite was monitored as illustrated in FIG. 5. As illustrated in FIG. 5, a channel was not monitored in the active layer not using the 2-D perovskite according to the comparative example 1. In contrast, it may be seen that the channels including the 2-D perovskite are distributed in an island form in the active layers of the embodiments 1 to 4 using BA₂PbI₄ as the 2-D perovskite and the number of channels and the diameter of the channel are increased as the content of the 2-D perovskite is increased.

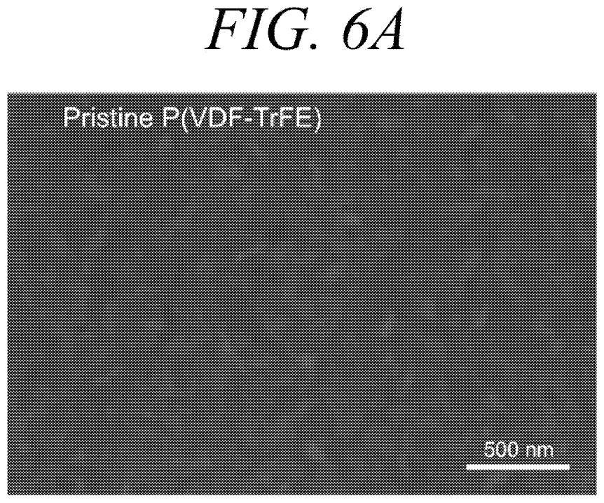

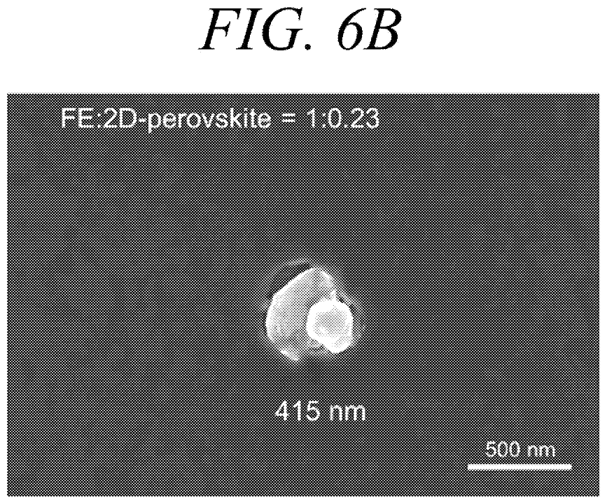

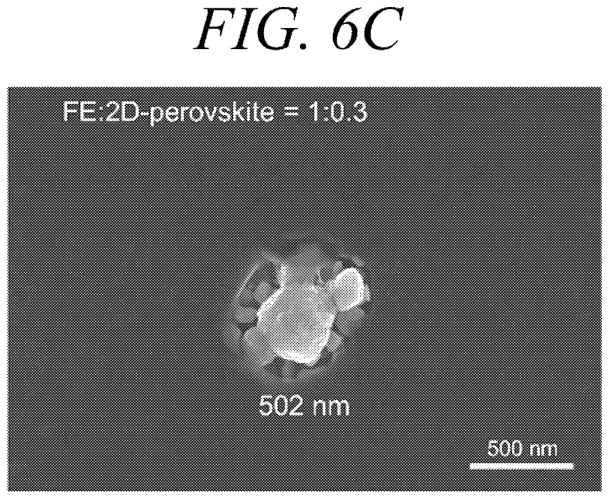

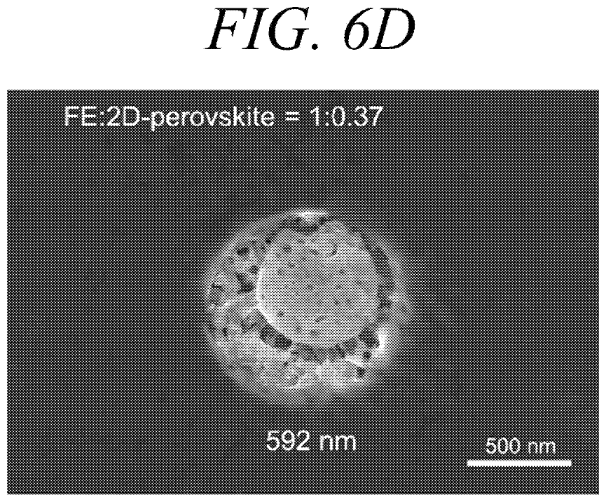

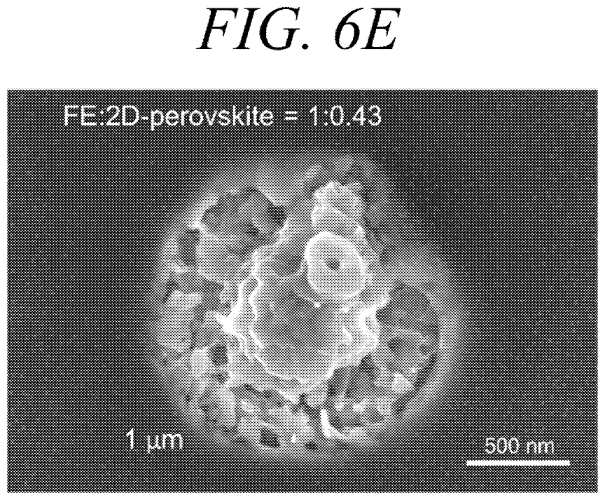

The increase in the diameter of the channel as the content of the 2-D perovskite increases can be observed in more detail from images captured by a field emission scanning electron microscope (FE-SEM; GEMINI500, Carl Zeiss Co.). As illustrated in FIG. 6, it may be seen that a channel was not monitored in the active layer not using the 2-D perovskite according to the comparative example 1, but the channel including the 2-D perovskite was formed to have the size of the diameter of 400 nm to 1 μm in the active layers of the embodiments 1 to 4. Specifically, it can be confirmed that the diameter of the channel increases up to a level of 1 μm as the content of the 2-D perovskite increases.

### Experiment Example 2. Evaluate the Resistance Switch Operation and Self-Rectifying Characteristic of the Resistive Memory Device

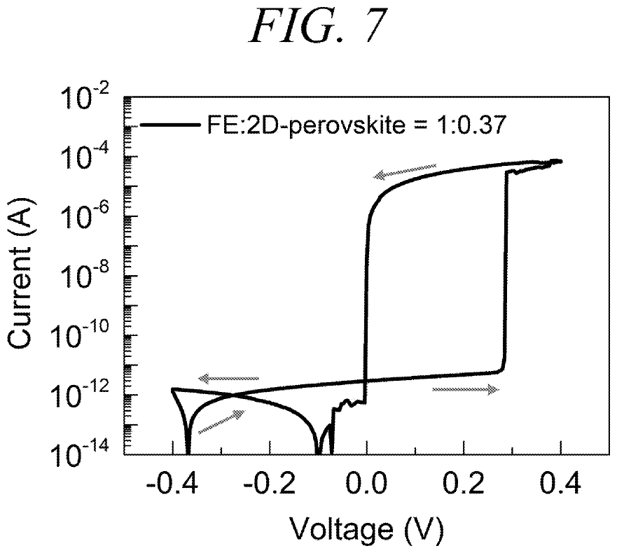

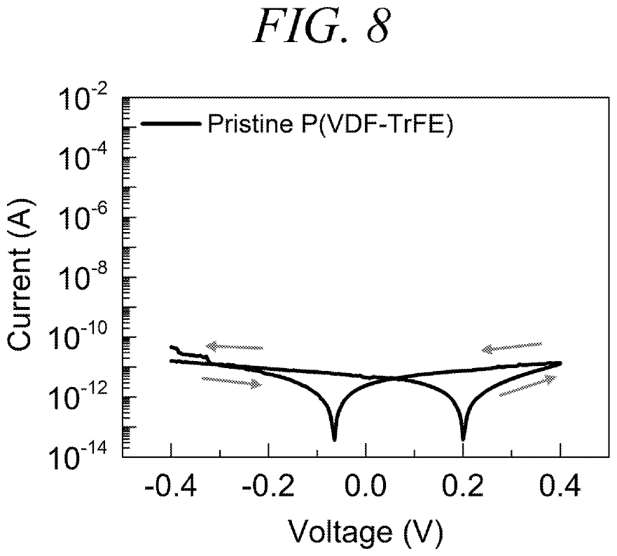

Resistance switching operations and self-rectifying characteristics of the self-rectifying resistive memory device of the embodiment 3 and the resistive memory devices of the comparative example 1 and 2 were evaluated. Specifically, the self-rectifying characteristic was measured under a DC voltage sweep (+0.4 V to −0.4 V) by applying a voltage to each of the top electrodes of the resistive memory devices of the embodiment and the comparative example. As may be seen from an I-V curve of FIG. 7, when a positive (+) voltage is swept from 0 V to +0.4 V, abrupt resistance switching occurs along with an ON current of about 10⁻⁵ A (or 15.5 A/m²) at +0.32 V, and the self-rectifying resistive memory device switches to the low resistance state (LRS) (SET operation). Thereafter, upon inverse sweep from +0.4 V to −0.4 V, the self-rectifying resistive memory device switches to the high resistance state (HRS) (RESET operation) along with an OFF current of about 10⁻¹¹ A (or 3.6×10⁻⁵ A/m²) at 0 V. As a result, the self-rectifying resistive memory device has an LRS/HRS (ON/OFF) current ratio of about 10⁶ upon reading at +0.1 V. It may be seen that from the results of the experiments, the resistance switch operation of the self-rectifying resistive memory device according to an embodiment of the present disclosure can be smoothly performed even at a low voltage (a set voltage is about 0.32 V). Furthermore, the I-V curve having a diode form in which in the self-rectifying resistive memory device according to an embodiment of the present disclosure, the SET operation in which a current sharply rises at the positive voltage is performed, but the current is extremely suppressed at the negative voltage appears. Accordingly, it may be seen that the self-rectifying resistive memory device has an excellent self-rectifying characteristic.

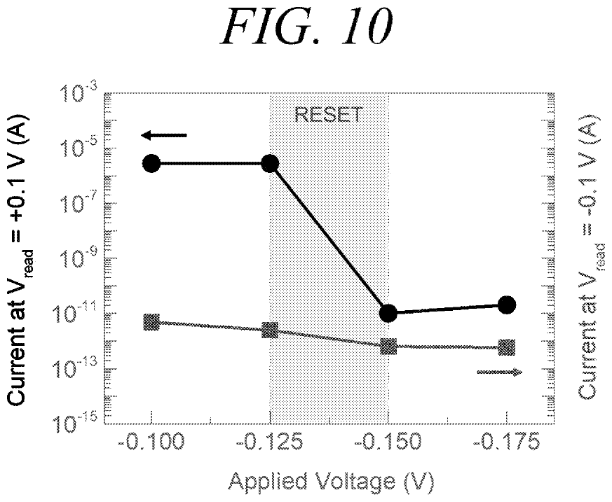

Furthermore, as may be seen from FIG. 10, the state in which the low resistance state of the self-rectifying resistive memory device of the embodiment 3 has been rectified is maintained unless an external application voltage does not drop to −0.15 V or less. When the external application voltage drops to −0.15 V or more, the LRS switches to the HRS. It may be seen that the reset voltage is-0.15 V.

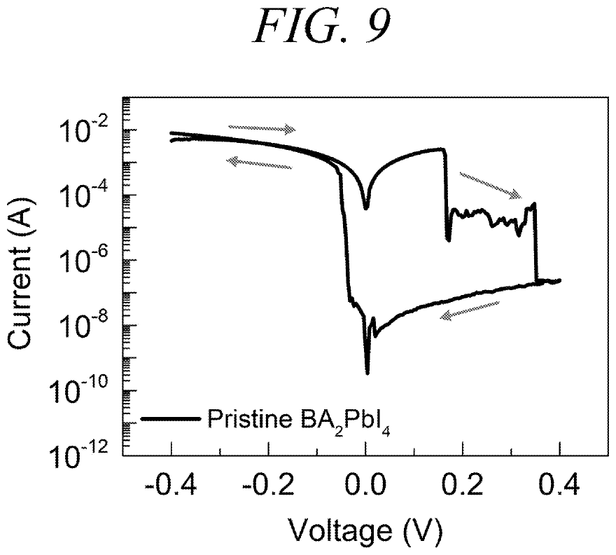

As may be seen from FIG. 8, it may be seen that the resistive memory device not including the 2-D perovskite according to the comparative example 1 has an I-V curve that is symmetrical left and right and a current flow is rarely present. That is, it may be seen that only characteristics of an insulator having low conductivity without rectification or a switching phenomenon appears and low voltage driving is also impossible. Furthermore, as shown in FIG. 9, the resistive memory device of Comparative Example 2, which does not include a ferroelectric, exhibits a nearly bipolar I-V curve. Because self-rectification does not occur, current flows under both positive and negative voltages, resulting in unstable switching regardless of a current direction.

### Experiment Example 3. Evaluate the Stability of the Self-Rectifying Resistive Memory Device According to Time

In order to evaluate the stability of the self-rectifying resistive memory device, the self-rectifying resistive memory device of the embodiment 3 was kept under room temperature and atmospheric conditions for a long time. Thereafter, experiments were conducted on a resistance switch operation of the self-rectifying resistive memory device by date by using the same method as that of the experiment example 2.

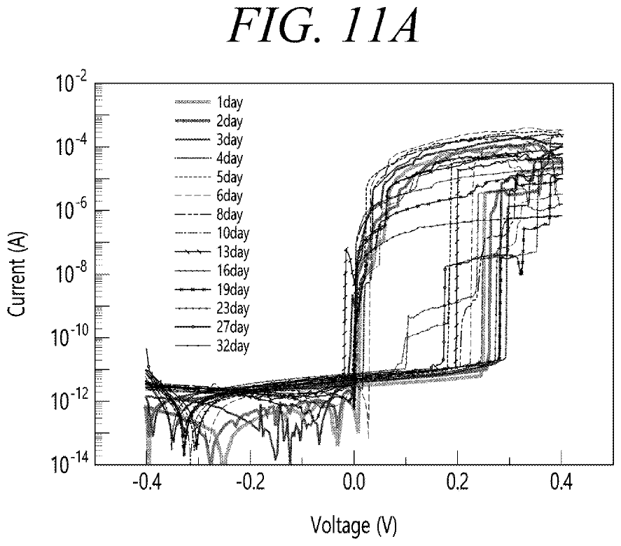

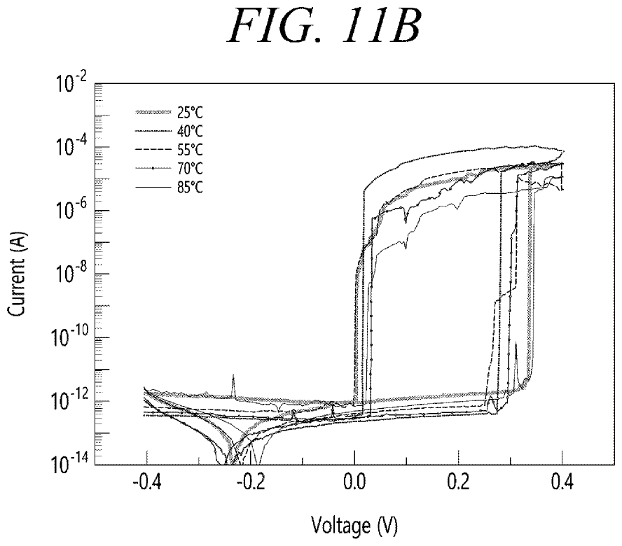

As shown in the I-V curve of FIG. 11A, the self-rectifying resistive memory device maintains similar hysteresis behavior from day 1 to day 32 under room-temperature atmospheric conditions. Specifically, the self-rectifying resistive memory device maintains a similar difference between currents in the LRS and the HRS. It may be seen that the self-rectifying resistive memory device has excellent atmosphere stability even in the atmosphere from the fact that the characteristics of nonvolatile memory are maintained.

### Experiment Example 4. Evaluate the Stability of the Self-Rectifying Resistive Memory Device at a High Temperature

In order to evaluate the stability of the self-rectifying resistive memory device, resistance switching operations of the self-rectifying resistive memory device of Embodiment 3 were tested at different time points using the same method as in Experimental Example 2 while increasing the temperature from room temperature (25 °C) to 85 °C.

As illustrated in an I-V curve of FIG. 11B, it may be seen that the self-rectifying resistive memory device of the embodiment 3 maintain hysteresis similar to that at a room temperature even at a high temperature. Furthermore, it may be seen that the self-rectifying resistive memory device has excellent thermal stability because a switching voltage or an LRS current does not significantly appear even at the high temperature.

### Experiment Example 5. Evaluate Data Retention and Endurance of the Self-Rectifying Resistive Memory Device

Data retention and endurance of the self-rectifying resistive memory device of the embodiment 3 according to time were evaluated.

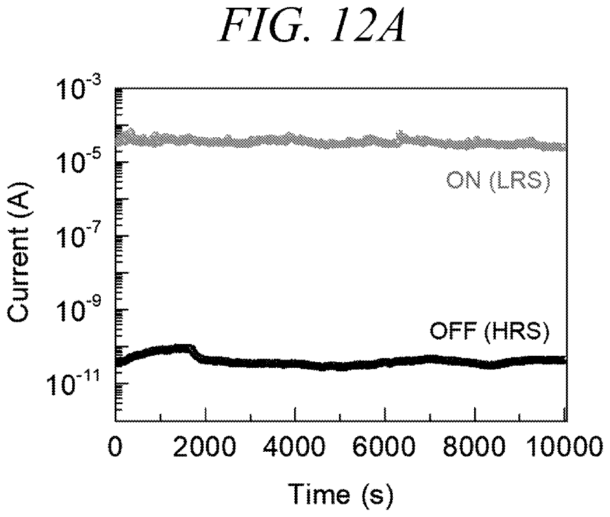

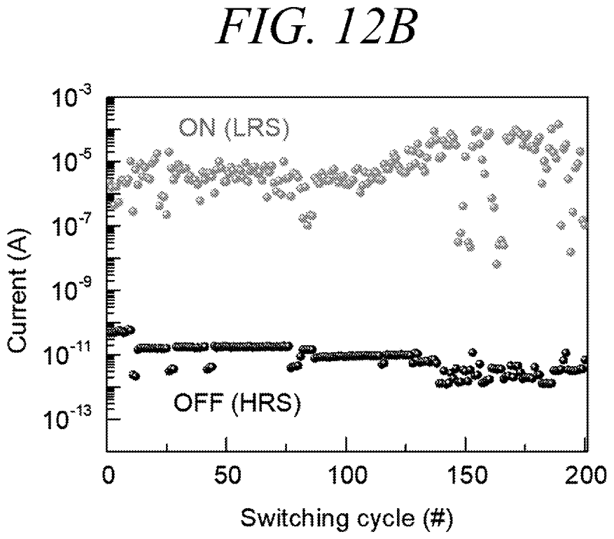

First, after the self-rectifying resistive memory device of the embodiment 3 is set as the ON state (LRS) and the OFF state (HRS) by sweeping a voltage in a range of −0.4 V to +0.4 V, each of the ON state (LRS) and OFF state (HRS) of the self-rectifying resistive memory device was monitored at a read voltage of +0.1 V for 10⁴ seconds or more. As illustrated in FIG. 12A, it may be seen that a current value in each of the ON state (LRS) and the OFF state (HRS) was stably maintained for 10⁴ seconds or more and thus the self-rectifying resistive memory device according to an embodiment of the present disclosure has an excellent data retention characteristic. In particular, it may be seen that a high current level was continuously maintained in the ON state and a current leakage was significantly suppressed even in the OFF state.

Next, in order to check whether the self-rectifying resistive memory device of the embodiment 3 can repetitively switch to the ON state (LRS) and the OFF state (HRS), switching endurance was evaluated. Specifically, the ON state was set by a voltage sweep up to −0.4 V, and the OFF state was set by a voltage sweep up to +0.4 V. Each of the ON state and the OFF state was measured at a read voltage of +0.1 V. Current values were monitored over a total of 200 switching cycles.

As shown in FIG. 12B, even after repetitive switching cycles, the ON state and the OFF state are stably maintained, and a clear difference between the currents in the ON state and the OFF state is maintained. Accordingly, it was found that the self-rectifying resistive memory device according to an embodiment of the present disclosure has excellent repeatability and high reproducibility.

### Experiment Example 6. Compare Performance Between the Self-Rectifying Resistive Memory Device According to the Embodiments of the Present Disclosure with the Existing Self-Rectifying Resistive Memory Device

Switching voltages, rectification ratios, etc. of the self-rectifying resistive memory device of the embodiment 3 and the existing self-rectifying resistive memory device are compared and illustrated in Table 1. In the existing self-rectifying resistive memory device, a metal oxide-single layer (comparative example “a”), a metal oxide-dual layer (comparative example “b”), a metal oxide-triple layer (comparative example “c”), a silicon compound (comparative example “d”), an organic compound (comparative example “e”), ferroelectric (comparative example “f”), ferroelectric and a semiconductor heterogeneous junction (comparative example “g” and “h”) were used as a component of the active layer.

TABLE 1

| | | | | | Data | Repetitive |
|---|---|---|---|---|---|---|
| | | | | V_{SET}/ | retention | operation |
| | Rectification | Switching ratio | Rectification | V_{RESET} | time | Lifespan |
| Classification | method | (I_{ON}/I_{OFF}@V_{READ}) | ratio | [V/V] | [s] | [cycle] |
| Embodiment 3 | Self-polarization | 10⁶@ + 0.1 V | 10⁶ | +0.3/−0.4 | >10⁴ | 100 (DC) |
| (Ag/P(VDF- | | | | | | |
| TrFE):BA₂PbI₄/ITO) | | | | | | |
| Comparative | Schottky barrier | 10⁴@ + 0.8 V | 2.4 × 10² | −4/+1.5 | 2 × 10³ | 100 (DC) |
| example “a” | | | | | | |
| (Pt/TaOₓ/n-Si) | | | | | | |
| Comparative | Schottky barrier | 10³@ + 7 V | 10⁴ | +12/−8 | >10⁶ | 100 (DC) |
| example “b” | | | | | | |
| (Pt/Ta₂O₅/HfO₂/ | | | | | | |
| TiN) | | | | | | |
| Comparative | Schottky barrier | 10⁶@ + 2.5 V | 10⁶ | +8/−4 | >10⁴ | N/A |
| example “c” | | | | | | |
| (Pt/Ta₂O₅/ | | | | | | |
| HfO₂₋ₓ/TiOₓ/Ti) | | | | | | |
| Comparative | P-i-N junction | 10⁴@ + 2 V | 10⁵ | +7.5/+4.5 | >10⁵ | 100 (DC) |
| example “d” | | | | | | |
| (p-Si/SiO₂/n-Si) | | | | | | |
| Comparative | Asymmetric | 10⁵@ + 0.05 V | 10⁵ | +0.2/−0.5 | >10⁴ | 100 (DC) |
| example “d” | molecular | | | | | |
| (Ag/FJU-23- | structure | | | | | |
| H₂O^{a)}/Ag) | | | | | | |
| Comparative | Asymmetric | 10³@ + 0.5 V | 10³ | +3/−3 | N/A | 200 (Pulse) |
| example “f” | potential barrier | | | | | |
| (Au/BaTiO₃/ | | | | | | |
| Nb:SrTiO₃) | | | | | | |
| Comparative | Schottky barrier | 10²@ + 3 V | 10³ | +20/−20 | >10⁵ | 10³ (Pulse) |
| example “g” | | | | | | |
| (Al/LiF/P(VDF- | | | | | | |
| TrFE):P3HT^{b)}/Ag) | | | | | | |
| Comparative | Schottky barrier | 10²@ + 3 V | 10⁴ | +20/−20 | 10⁴ | 10⁷ (Pulse) |
| example “h” | | | | | | |
| (Al/P(VDF- | | | | | | |
| TrFE):ZnO/Pt) | | | | | | |

Wherein “a” is a metal-organic framework (MOF) represented by {[ZnL(H₂O)]₃(H₂O)₄}ₙ, and “b” is poly(vinylidene fluoride-co-trifluoroethylene):poly(3-hexylthiophene-2,5-diyl)

What is claimed is:

1. A self-rectifying resistive memory device comprising a bottom electrode, a top electrode, and an active layer interposed between the bottom electrode and the top electrode,
wherein the active layer comprises a channel configured to penetrate an inside of the active layer and to connect the top electrode and the bottom electrode and ferroelectric,
the channel comprises two-dimensional (2-D) perovskite, and
an average diameter of the channels is 0.1 μm or more and 2 μm or less.

2. The self-rectifying resistive memory device according to claim 1, wherein the 2-D perovskite is present in an amount of 10 parts by weight or more and 90 parts by weight or less based on 100 parts by weight of the ferroelectric.

3. The self-rectifying resistive memory device according to claim 1, wherein the ferroelectric has a polarization value of 1 μC/cm² or more and 10 μC/cm² or less.

4. The self-rectifying resistive memory device according to claim 1, wherein the ferroelectric has a polarization value of 5 μC/cm² or more and 7 μC/cm² or less.

5. The self-rectifying resistive memory device according to claim 1, wherein the 2-D perovskite is a compound expressed by Chemical Formula 1:
Y₂MX₄ [Chemical Formula 1]
In the Chemical Formula 1,
the Y is butyl ammonium (BA), pentylammonium (PA), hexylammonium (HA), ammonium valeric acid (AVA), naphthylmethyl ammonium (NMA), phenylmethylammonium (PMA), or phenylethyl ammonium (PEA),
the M is Cu, Fe, Sn, Zn, Pb, Mn, Ge, Ni, Co, Cr, Pd, Cd, or Yb, and
the X is F, Cl, Br, or I.

6. The self-rectifying resistive memory device according to claim 1, wherein the 2-D perovskite comprises one or more selected from a group consisting of BA₂PbI₄, PEA₂PbI₄, and BA₂PbCl₄.

7. The self-rectifying resistive memory device according to claim 1, wherein the ferroelectric comprises a (co)polymer comprising one or more monomers selected from a group consisting of vinylidene fluoride, trifluoroethylene, chlorofluoroethylene, and chlorotrifluoroethylene.

8. The self-rectifying resistive memory device according to claim 1, wherein the ferroelectric comprises one or more selected from a group consisting of PVDF, P(VdF-TrFE), P(VdF-TrFE-CFE), and P(VdF-TrFE-CTFE).

9. The self-rectifying resistive memory device according to claim 1, wherein a thickness of the active layer is 0.1 μm or greater and 1 μm or less.

10. The self-rectifying resistive memory device according to claim 1, wherein the top electrode comprises one or more selected from a group consisting of Ag, Au, Al, Cu, Ni, Mg, Fe, Cr, Ti, Pt, Ru, Co, Mo, W, Li, Na, K, Cs, and Zn.

11. The self-rectifying resistive memory device according to claim 1, wherein the bottom electrode comprises one or more selected from a group consisting of ITO, FTO, AZO, IZO, ZTO, and IZTO.

12. A method of manufacturing a self-rectifying resistive memory device, the method comprising:
preparing an active layer slurry comprising a two-dimensional (2-D) perovskite, a ferroelectric, and a solvent;
forming an active layer by coating the active layer slurry on one surface of a bottom electrode; and
stacking a top electrode on a surface of the active layer opposite to the bottom electrode,
wherein the 2-D perovskite is present in an amount of 10 to 90 parts by weight based on 100 parts by weight of the ferroelectric.

13. The method according to claim 12, wherein the forming of the active layer comprise coating the active layer slurry by a spin-coating method.
